(19) United States
(12) Patent Application Publication
(10) Pub. No.: US 2012/0119047 A1
(43) Pub. Date: May 17, 2012

(54) Electronic Device Holder

(75) Inventors: Christopher Forrest Lumpkin, Steamboat Springs, CO (US); Lesley Anne Mentzel-Lumpkin, Steamboat Springs, CO (US); Tony Benson Lumpkin, Austin, TX (US)

(73) Assignee: Christopher F Lumpkin, Steamboat Springs, CO (US)

(21) Appl. No.: 13/293,264

(22) Filed: Nov. 10, 2011

Related U.S. Application Data
(60) Provisional application No. 61/412,637, filed on Nov. 11, 2010.

(51) Int. Cl. H05K 7/00

(52) U.S. Cl. 248/274.1; 248/309.1

(57) ABSTRACT

A device used to support an IPad™ or similar for use by the operator to have their hands free and to be able to position the device in the desired location for best use.

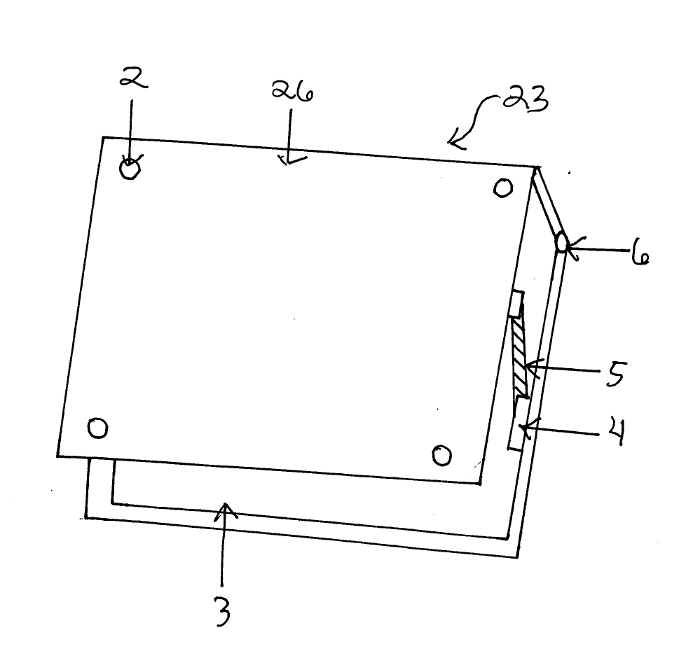

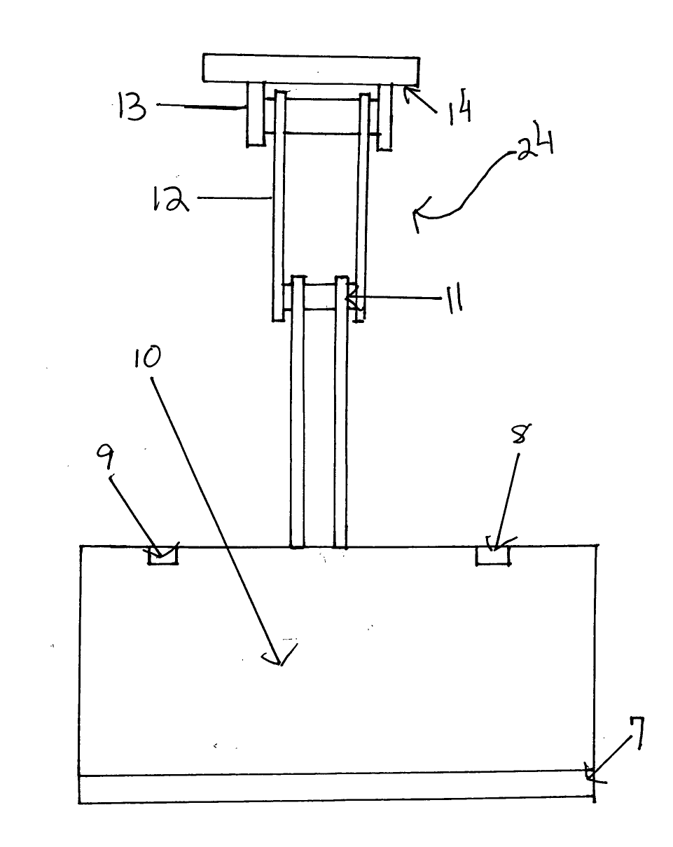

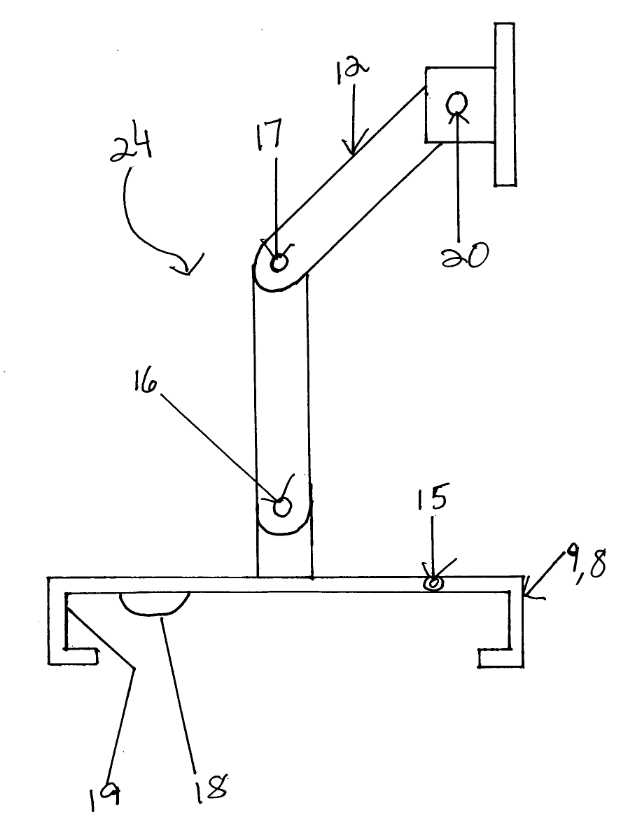

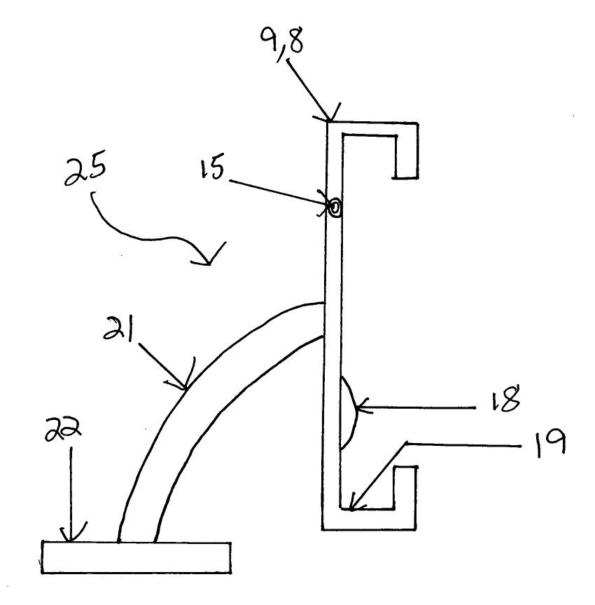

### BACKGROUND OF THE INVENTION

Devices in the past have been made to allow the use of a holder to create a platform or holding device to allow the user to hold a book or similar in place. This invention is designed to hold and iPad™ or similar electronic tablet or device for an operator's use in different applications.

### BRIEF DESCRIPTION OF DRAWINGS

#1 A side view of the first embodiment of the invention

#2 A front view of another embodiment of the invention

#3 A side view of #2 embodiment of the invention

#4 A front view of yet another embodiment of the invention

### BRIEF SUMMARY OF THE INVENTION

Devices in the past have been made to allow the use of a holder to create a platform or holding device to allow the user to hold a book or similar in place. This invention is designed to hold an iPad™ or similar electronic tablet or device for an operator's use in different applications.

This invention's intended users are any individuals who would benefit from a device to hold an iPad™ or similar electronic tablet or device to allow for hands-free viewing of the device while leaving the user's hands available to perform another task. Examples include, but are not limited to, cooking, medical procedures, writing, mechanical tasks, etc.

### DETAILED DESCRIPTION OF THE INVENTION

23 has a mounting plate 26 to allow the invention to be mounted to a surface by the means of mounting though holes 2. The invention 23 has hinge 6 which allow the device to open to the desired amount for the user. The invention 23 has a hinge 5 or series of hinges 5 and mounting slots 4 for the manipulation of the invention 23 and allow it to be held in place. The invention 23 of the first embodiment has the means to hold the device in place by using 3.

A second embodiment 24 has a series of pivot points 11,13,16,17, and 20 on the arm for manipulation. The invention 24 of the second embodiment further has a set of tabs 8 and 9 to hold the device in place. The invention 24 has a lip 7 to also hold the device in place. The invention 24 has a set of arms 12 to aid in manipulating the device to the desired location. The invention 24 has the platform 10 for where the device is to be placed. The invention 24 has the slot 19 where the device slides into by pulling back on hinge 15 to allow the device to slide into slot 19 of the invention 24. Once the invention 24 is in slot 19, the tabs 8 and 9 can be released to capture the device by us of hinge 15. The invention 24 also has a piece 18 which allows pressure to be put on the device in ensure it is securely in place. The invention 24 further has a mounting plate 14 that could be fixed plate magnet or clamp to keep the invention 24 secure.

A third embodiment 25 has a manipulating arm 21 which can allow the user to place the invention 25 in many different locations. The invention 25 has a mounting bracket 22 which could be in the form of a clamp, fixed mount, or magnet to keep the arm 21 of the invention 25 secure.

1. The device comprising:
A means to receive an IPad™ for mechanically supporting it, to be held hands free. Further comprising the means to allow the person to position it where they desire.

2. The device according to claim 1, further comprising:
The means to allow the IPad™ to be secured so it can be orientated in many different positions and remain secure in the device.

3. The device according to claim 1:
Is designed to allow an IPad™ to be held hands free, but is not limited to an IPad™.

4. The device according to claim 1, further comprising:
The means of a flexible and or a manipulating arm to position the device to the desired position.

5. The device according to claim 1, further comprising:
The arm can be mounted permanently and or temporary clamp device.

6. A device comprising:
A means to receive an electronic device for mechanically supporting it, to be held hands free.

7. The device according of claim 6, further comprising:
The means to allow the electronic device to be secured, so it can be orientated in many different positions without falling from the device.

8. The device according of claim 6, further comprising:
The means of a flexible and or a manipulating arm to position the device to the desired position.

9. The device according of claim 6, further comprising:
The arm can be mounted permanently and or temporary clamp device.

10. A device comprising:
The means to allow the user to view and use the IPad™ and or similar device in applications where the use of both hands are needed a portion of the time during the use of the device.
